(19) United States
(12) Patent Application Publication
(10) Pub. No.: US 2020/0144098 A1
(43) Pub. Date: May 7, 2020

(54) SUBSTRATE-SUPPORTING DEVICE AND METHOD OF POLISHING SUBSTRATE USING THE SAME

(71) Applicant: SAMSUNG DISPLAY CO., LTD., Yongin-si (KR)

(72) Inventors: Byoung Kwon CHOO, Yongin-si (KR); Seungbae KANG, Yongin-si (KR); Joon-Hwa BAE, Yongin-si (KR); Bonggu KANG, Yongin-si (KR); Jeong Min PARK, Yongin-si (KR); Heesung YANG, Yongin-si (KR); Woo Jin CHO, Yongin-si (KR)

(21) Appl. No.: 16/574,303

(22) Filed: Sep. 18, 2019

(30) Foreign Application Priority Data
Nov. 5, 2018 (KR) 10-2018-0134429

(51) Int. Cl. H01L 21/687; B24B 37/27; H01L 21/02

(52) U.S. Cl. CPC H01L 21/68757; B24B 37/27; H01L 21/02013; H01L 21/68735; H01L 21/02592; H01L 21/02532; H01L 21/02595

(57) ABSTRACT

A substrate-supporting device may include a porous chuck disposed in a frame, an adsorption pad disposed on the porous chuck, and an adhesive layer disposed between the porous chuck and the adsorption pad. The adsorption pad may include an elastic layer and a porous layer combined with the elastic layer. Each of the adhesive layer, the elastic layer and the porous layer may include through-portions respectively extending in a thickness direction. The adsorption pad may have a value of 100 or less based on Asker C hardness.

### CROSS-REFERENCE TO RELATED APPLICATION

Korean Patent Application No. 10-2018-0134429, filed on Nov. 5, 2018, in the Korean Intellectual Property Office, and entitled: “Substrate-Supporting Device and Method of Polishing Substrate Using the Same,” is incorporated by reference herein in its entirety.

### BACKGROUND

### 1. Field

Example embodiments relate to a substrate-supporting device and a method of polishing a substrate using the same.

### 2. Description of the Related Art

In a chemical mechanical polishing (CMP) process for polishing a wafer substrate, a wafer substrate-supporting device of a membrane chuck structure is used to support the wafer substrate. In this wafer substrate-supporting device of the membrane chuck structure, a wafer is attracted to a membrane of a silicon material, and then the entire wafer is uniformly pressurized by applying an air pressure.

When the wafer supporting device of the membrane chuck structure is directly used in a display process, since the size of a display substrate is about 20 times larger than that of a semiconductor wafer substrate, problems such as pressure control, glass breakage, etc., may occur. In response thereto, a glass substrate is placed on a frame and then an air in the frame is removed to make an inside in a vacuum state. However, the pressure applied in a subsequent CMP process may not be uniformly transmitted to the glass substrate, so that a polishing unevenness may occur.

### SUMMARY

Embodiments are directed to a substrate-supporting device, including a porous chuck in a frame, an adsorption pad on the porous chuck, and an adhesive layer between the porous chuck and the adsorption pad. The adsorption pad includes an elastic layer and a porous layer combined with the elastic layer. Each of the adhesive layer, the elastic layer, and the porous layer includes through-portions respectively extending in a thickness direction. The adsorption pad has an Asker C hardness value of 100 or less.

Each of the elastic layer and the porous layer of the adsorption pad may include at least one of polyurethane, polyacryl, polydimethylsiloxane (PDMS) and polyurethane acrylate (PUA).

Each of the elastic layer and the porous layer of the adsorption pad may include a fabric impregnated with a polymer.

The elastic layer and the porous layer of the adsorption pad may include different materials from each other.

The elastic layer and the porous layer of the adsorption pad may include a same material.

The porous layer of the adsorption pad may include pores having a diameter less than 100 μin.

The through-portions may have a diameter less than 100 μm.

The adsorption pad may have an Asker C hardness value of 50 or less.

The adhesive layer may include first through-portions. The elastic layer may include second through-portions. At least a portion of the first through-portions may be connected to the second through-portions.

The elastic layer may include second through-portions. The porous layer may include third through-portions. At least a portion of the second through-portions may be connected to the third through-portions.

The elastic layer may include second through-portions. The porous layer may include third through-portions. The second and third through-portions are aligned and connected to each other.

A thickness of the adsorption pad 400 may be 800 to 6,000 μm. A thickness of each of the elastic layer and the porous layer of the adsorption pad may be 400 to 3,000 μm.

The porous chuck may be formed of a rigid-body structure including a ceramic material.

The adhesive layer and the adsorption pad may be integrally formed as a single unit.

Embodiments are also directed to a method of polishing a substrate, including disposing a substrate on a substrate-supporting device including a porous chuck, an adhesive layer, and an adsorption pad sequentially stacked in a frame, fixing the substrate to the substrate-supporting device by applying a negative pressure, and polishing the substrate using a slurry.

The adsorption pad may include an elastic layer and a porous layer combined with the elastic layer. Each of the adhesive layer, the elastic layer and the porous layer may include through-portions respectively extending in a thickness direction. The adsorption pad may have an Asker C hardness value of 100 or less.

Each of the elastic layer and the porous layer of the adsorption pad may include at least one selected from the group of polyurethane, polyacryl, polydimethylsiloxane (PDMS) and polyurethane acrylate (PUA).

Each of the elastic layer and the porous layer of the adsorption pad may include a fabric impregnated with a polymer.

The substrate may include a silicon layer.

The silicon layer may include amorphous silicon or polysilicon.

### BRIEF DESCRIPTION OF THE DRAWINGS

Features will become apparent to those of skill in the art by describing in detail exemplary embodiments with reference to the attached drawings in which:

FIG. 1 illustrates a schematic view of a substrate-supporting device in accordance with example embodiments.

FIGS. 2 to 6 illustrate plan views and cross-sectional views of a substrate-supporting device in accordance with example embodiments.

FIGS. 7 to 11 illustrate cross-sectional views of stages of a method of polishing a substrate in accordance with example embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

A substrate-supporting device and a method of polishing a substrate using the same in accordance with example embodiments will be described more fully hereinafter with reference to the accompanying drawings.

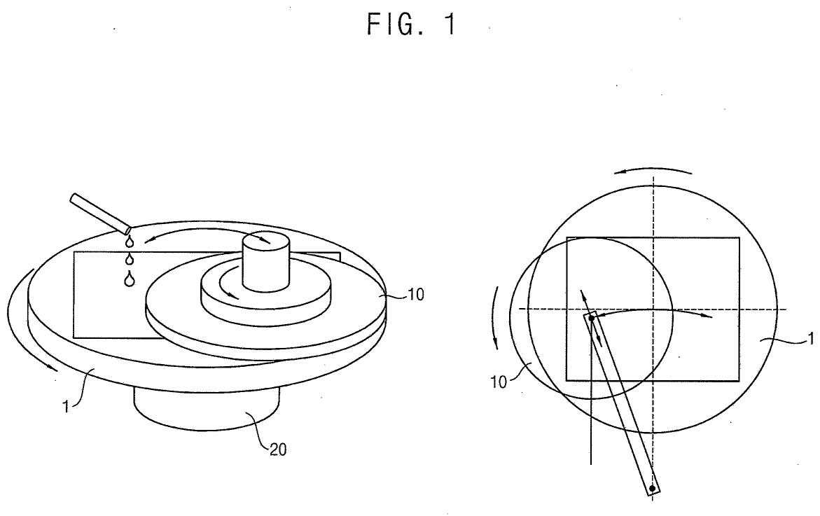

FIG. 1 illustrates a schematic view of a substrate-supporting device in accordance with example embodiments. For example, FIG. 1 illustrates a schematic view of a substrate-supporting device included in a substrate polishing device used in a polishing process, e.g., a chemical mechanical polishing (CMP) process, during a manufacturing process of a display device.

Referring to FIG. 1, a substrate-supporting device 1 may be formed between a top board 10 and a bottom board 20 in a substrate polishing device used in a CMP process. For example, the substrate polishing device may include the top board 10, the bottom board 20 and the substrate-supporting device 1 between the top board 10 and the bottom board 20. The top board 10 may include a polishing pad, and the bottom board 20 may include an opening for removing or injecting an interior air of the substrate-supporting device. The opening may extend through a lower surface of the substrate-supporting device 1 and may be connected thereto.

A polishing method in which the substrate is attracted to the substrate-supporting device 1 by applying a negative pressure to the substrate-supporting device 1, and then the polishing pad in the top board 10 is rotated clockwise or counterclockwise to polish a surface of the substrate, that is, an Oscar polishing method is illustrated in FIG. 1. In some implementations, the substrate-supporting device 1 may be used in an in-line polishing method in which a plurality of substrates are attracted to a belt extending in one direction, and then the belt is moved for friction with a polishing pad to polish a surface of the substrate. In some implementations, the substrate-supporting device 1 may be also used in a hybrid polishing method in which a polishing pad is rotated clockwise or counterclockwise to polish a surface of a substrate, as in the Oscar polishing method, while using a belt as in the in-line polishing method.

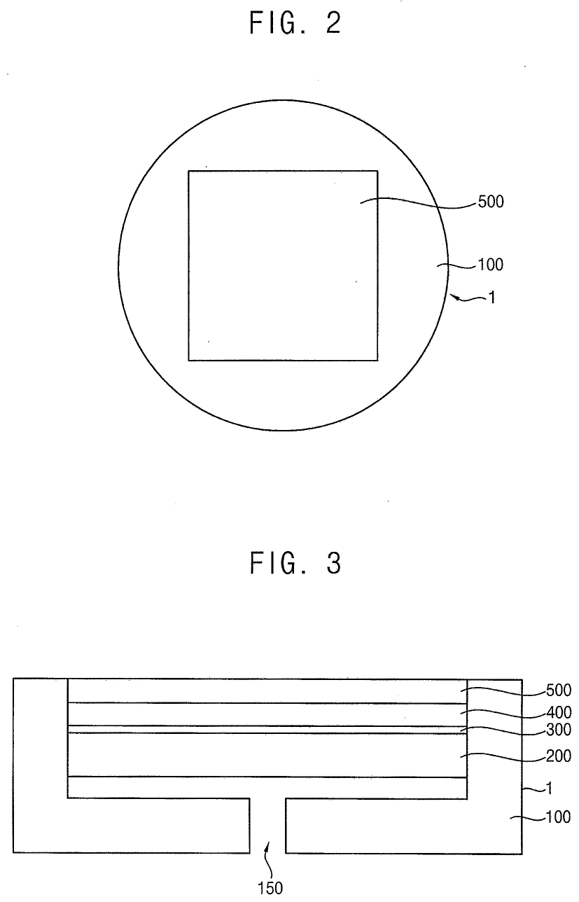

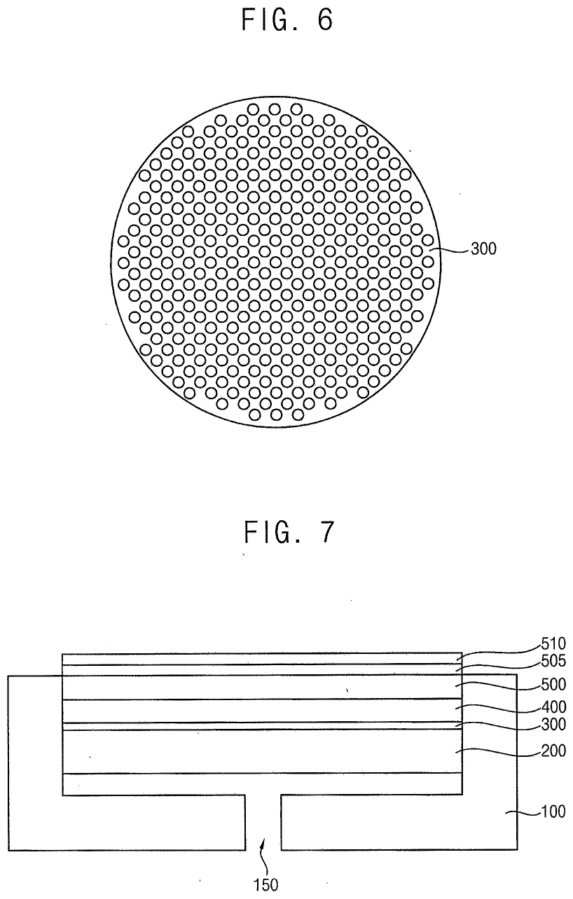

FIGS. 2 to 6 illustrate plan views and cross-sectional views of a substrate-supporting device 1 in accordance with example embodiments. For example, FIGS. 2 and 6 are the plan views, and FIGS. 3 to 5 are the cross-sectional views.

Referring to FIGS. 2 and 3, the substrate-supporting device 1 may include a porous chuck 200, an adhesive layer 300 and an adsorption pad 400 sequentially disposed on a frame 100. A substrate 500 may be disposed on the adsorption pad 400 to perform a polishing process. After performing the polishing process, the substrate 500 may be detached from the substrate-supporting device 1. An opening 150 serving as a passage for removing or injecting an air inside the frame 100 may be formed in a lower portion of the frame 100. The opening 150 may extend through the lower surface of the frame 100 and may be connected with the bottom board 20 of the substrate polishing device 1 (see FIG. 1). In one embodiment, upper surfaces of both sides of the frame 100 may be formed at substantially the same height as an upper surface of the substrate 500.

The porous chuck 200 may include a plurality of air holes having an average diameter of, e.g., 100 μm or less. The air holes in the porous chuck 200 may have a shape similar to a circle or an ellipse.

The adhesive layer 300 may serve as a double-sided tape to connect an upper surface of the porous chuck 200 and a lower surface of the adsorption pad 400 to each other. In some implementations, the adhesive layer 300 may be omitted.

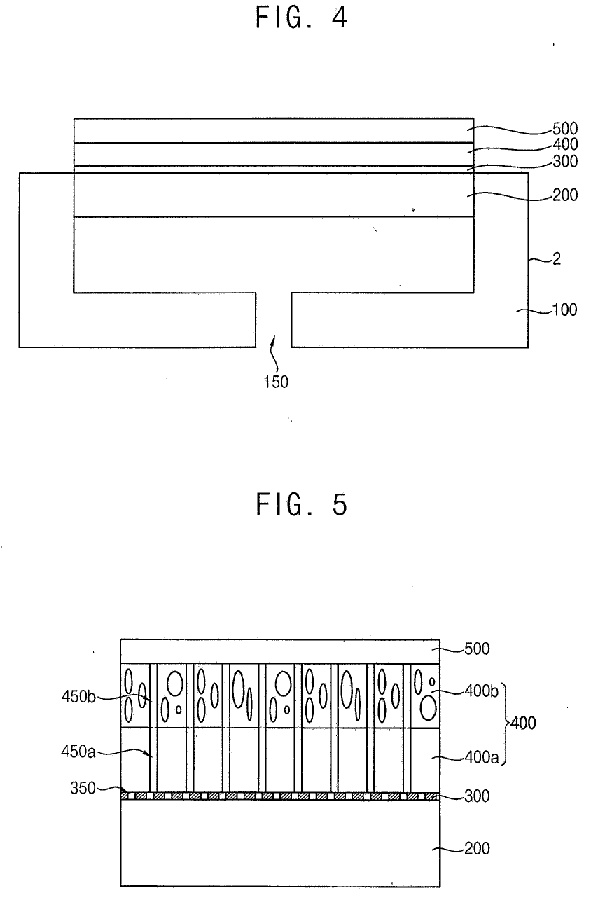

Referring to FIG. 5, a plurality of first through-portions 350 passing through a lower surface and an upper surface of the adhesive layer 300 and extending in a thickness direction may be formed in the adhesive layer 300. In one embodiment, the first through-portion 350 may have a shape similar to a cylinder having a diameter of 100 μm or less.

The adsorption pad 400 may include an elastic layer 400a that does not include pores therein, and a porous layer 400b that includes a plurality of pores therein.

The pores in the porous layer 400b may have a shape similar to a circle or an ellipse and may have an average diameter of 100 μm or less, thereby preventing the shape of the pores in the porous layer 400b from being transferred onto the surface of the substrate 500 after the polishing process, which could happen if the size of the pores in the porous layer 400b that directly contact a back plane of the substrate 500 were to be larger than 100 Accordingly, stain defects may be prevented or minimized.

In example embodiments, each of the elastic layer 400a and the porous layer 400b of the adsorption pad 400 may be formed to have a thickness of 400 to 3,000 μm. The elastic layer 400a and the porous layer 400b of the adsorption pad 400 may be formed with a thickness ratio of about 1:1. In some implementations, the elastic layer 400a and the porous layer 400b of the adsorption pad 400 may be formed to have different thicknesses depending on characteristics of the polishing process. An overall thickness of the adsorption pad 400 may be 800 to 6,000 μm.

The elastic layer 400a of the adsorption pad 400 may include a second through-portion 450a passing through a lower surface and an upper surface of the elastic layer 400a and extending in a thickness direction. The porous layer 400b of the adsorption pad 400 may include a third through-portion 450b passing through a lower surface and an upper surface of the porous layer 400b and extending in a thickness direction. In one embodiment, each of the second and third through-portions 450a and 450b may have a shape similar to a cylinder having a diameter of 100 μm or less.

In example embodiments, the second and third through-portions 450a and 450b may be formed by forming a mask on the adsorption pad 400, and then performing an etching process using the mask as an etching mask.

The second and third through-portions 450a and 450b in the elastic layer 400a and the porous layer 400b, respectively, of the adsorption pad 400 may be aligned and connected to each other. The second and third through-portions 450a and 450b may not be aligned with the plurality of first through-portions 350 in the adhesive layer 300. The second and third through-portions 450a and 450b may be connected to at least a portion of the plurality of first through-portions 350 to that the air inside the frame 100 may be removed or injected through the first to third through-portions 350, 450a and 450b.

In example embodiments, after forming a first mask on the porous layer 400b, a first etching process using the first mask as an etching mask may be performed to form the third through-portion 450b. The adsorption pad 400 may then be inverted to dispose the elastic layer 400a so that the lower surface thereof faces upwardly. A second mask may be formed on the lower surface of the elastic layer 400a, and a second etching process using the second mask as an etching mask may be performed to form the second through-portion 450a.

In this case, the second and third through-portions 450a and 450b may be formed not to be aligned to each other. However, the second through-portions 450a may be connected to at least a portion of the third through-portions 450b, and the air inside the frame 100 may be removed or injected through the second and third through-portions 450a and 450b. The second and third through-portions 450a and 450b may also be connected to at least a portion of the plurality of first through-portions 350 so that the air inside the frame 100 may be removed or injected through the first to third through-portions 350, 450a and 450b. For example, at least each of the first to third through-portions 350, 450a and 450b may be partially connected to each other, and thus may serve as a passage that air inside the frame 100 may move therethrough.

Accordingly, air inside the frame 100 may be removed to adsorb the lower surface of the substrate 500, or air may be injected to detach the substrate 500. The porous chuck 200, the adhesive layer, and the elastic layer 400a and the porous layer 400b of the adsorption pad 400 may include the air holes, and the first to third through-portions 350, 450a and 450b, respectively, may serve as passages that air may move therethrough.

Each of the elastic layer 400a and the porous layer 400b of the adsorption pad 400 may have a hardness value of 100 or less, preferably 10 or more and 50 or less, based on Asker C hardness. If the Asker C hardness value of the adsorption pad 400 were to be more than 100, the stiffness of the adsorption pad 400 may be increased, and thus the abrasive rate of the substrate 500 may be increased. However, the elasticity of the adsorption pad 400 may be decreased, the pressure generated in the polishing process may not be properly absorbed, and thus the surface of the substrate 500 may not be uniformly polished during the polishing process. If Asker C hardness value of the adsorption pad 400 is 100 or less, the stiffness of the adsorption pad 400 may be decreased, and thus the abrasive rate of the substrate 500 may be decreased. However, the elasticity of the adsorption pad 400 may be increased, and the surface of the substrate 500 may be uniformly polished during the polishing process. When the Asker C hardness value of the adsorption pad 400 is 50 or less, the elasticity of the adsorption pad 400 may be greatly increased, and the surface of the substrate 500 may be more uniformly polished during the polishing process.

The frame 100 may include a metallic material. The porous chuck 200 may be formed as a rigid-body structure including, e.g., a ceramic material. The adhesive layer 300 may include a material having an adhesion force, e.g., an acrylic material. The adhesive layer 300 may serve as a double-sided tape. Each of the elastic layer 400a and the porous layer 400b of the adsorption layer 400 may include a material having an elasticity, e.g., at least one selected from the group of polyurethane, polyacryl, polydimethylsiloxane (PDMS) and polyurethane acrylate (PUA). The substrate 500 may include an insulating material, e.g., glass, quartz and plastic. The plastic may include, e.g., polyethylene terephthalate, polyethylene naphthalate, polyether ketone, polycarbonate, polyarylate, polyether sulfone, polyimide, etc. In an embodiment, each of the elastic layer 400a and the porous layer 400b of the adsorption layer 400 may further include a fabric material, e.g., non-woven fabric.

The elastic layer 400a and the porous layer 400b may be formed to have the same material as each other. In some implementations, the elastic layer 400a and the porous layer 400b may be formed to have different materials from each other. For example, in some implementations, the elastic layer 400a and the porous layer 400b may include the same material, may be integrally formed, and may be inseparable from each other. In some implementations, the elastic layer 400a and the porous layer 400b may include different materials, may be individually formed, and may be separable from each other.

In example embodiments, after forming a foam composition on an adsorption layer, the elastic layer 400a and the porous layer 400b may be formed by foaming, curing and patterning an upper surface of the adsorption layer.

In some implementations, after forming a foam composition on a first adsorption layer, the porous layer 400b may be formed by foaming, curing and patterning an upper surface of the first adsorption layer. After reversing the porous layer 400b to be disposed so that a lower surface thereof faces upwardly, a second adsorption layer may be formed, and the elastic layer 400a may be formed by patterning the second adsorption layer. In this case, the adsorption pad 400 may be formed by including a material having an adhesion force, e.g., the adhesive layer 300 between the elastic layer 400a and the porous layer 400b.

In example embodiments, the adhesive layer 300 and the adsorption pad 400 may be formed to be separable from each other. In some implementations, the adhesive layer 300 and the adsorption pad 400 may be integrally formed. The adhesive layer 300 and the adsorption pad 400 may be individually formed and separately replaced as desired. As mentioned above, in some implementations, the adhesive layer 300 and the adsorption pad 400 may be integrally formed so be inseparable from each other and may be replaceable at one time.

FIG. 4 illustrates a cross-sectional view of a substrate-supporting device 2 in accordance with another embodiment. This substrate-supporting device 2 is substantially the same as or similar to the substrate-supporting device 1 in FIGS. 2 to 3, except for the shape of the frame. Accordingly, like reference numerals refer to like elements, and detailed descriptions thereon are omitted herein.

Referring to FIG. 4, upper surfaces of both sides of the frame 100 may be formed at substantially the same height as an upper surface of the porous chuck 200. Accordingly, the adsorption pad 400 may be easily attached on the porous chuck 200 by the adhesive layer 300.

FIG. 6 is a plan view illustrating that a plurality of second through-portions 350 in the adhesive layer 300 may be formed at regular intervals.

As described above, the substrate 500 may be disposed, on the porous chuck 200, the adhesive layer 300 and the adsorption pad 400 sequentially stacked in the frame 100, and the opening 150, which may extend through the lower surface of the frame 100, may be connected with the bottom board 20 of the substrate polishing device (see FIG. 1) and may serve as a passage for removing or injecting the air inside the frame 100. The opening 150 may be formed in a lower portion of the frame 100. The adsorption pad 400 may include the elastic layer 400a, which may not include air holes, and the porous layer 400b, in which may include a plurality of air holes.

The plurality of first through-portions 350 passing through the lower surface and the upper surface of the adhesive layer 300 and extending in the thickness direction may be formed in the adhesive layer 300. The elastic layer 400a of the adsorption pad 400 may include the second through-portion 450a passing through the lower surface and the upper surface of the elastic layer 400a and extending in the thickness direction. The porous layer 400b of the adsorption pad 400 may include the third through-portion 450b passing through the lower surface and the upper surface of the porous layer 400b and extending in the thickness direction.

The second and third through-portions 450a and 450b in the elastic layer 400a and the porous layer 400b, respectively, of the adsorption pad 400 may be aligned and connected to each other. In some implementations, the second and third through-portions 540a and 450b may not be aligned with the plurality of first through-portions 350. In some implementations, the second and third through-portions 450a and 450b may be connected to at least some of the plurality of first through-portions 350. In some implementations, the second and third through-portions 450a and 450b may not be aligned with each other. In some implementations, at least a portion of the second through-portions 450a and at least a portion of the third through-portions 450b may be connected to each other, and at least a portion of the first through-portions 350 and at least a portion of the second through-portions 450a may also be connected to each other. For example, at least some of each of the first to third through-portions 350, 450a and 450b may be connected to each other.

Accordingly, when air inside the frame 100 is removed to adsorb the substrate 500 or when air is injected into the frame 100 to detach the substrate 500, the porous chuck 200, the adhesive layer 300, and the elastic layer 400a and the porous layer 400b of the adsorption pad 400 may be connected to the opening 150, by way of the first to third through-portions 350, 450a and 450b, respectively, and thus may serve as passages that air may move therethrough.

Each of the elastic layer 400a and the porous layer 400b of the adsorption layer 400 may include a material having an elasticity, e.g., at least one selected from the group of polyurethane, polyacryl, polydimethylsiloxane (PDMS) and polyurethane acrylate (PUA), and may have a hardness value of 100 or less, preferably 10 or more and 50 or less, based on an Asker C hardness scale. Accordingly, the hardness of the adsorption pad 400 may not be large, and the adsorption pad 400 may have the elasticity, so that the pressure may be uniformly applied to the substrate 500, and the uniformity of the surface of the substrate 500 after the polishing process may be improved.

FIGS. 7 to 11 illustrate cross-sectional views of a method of polishing a substrate in accordance with example embodiments.

This substrate-supporting device may be substantially the same as or similar to the substrate-supporting device 1 or 2 in FIGS. 1 to 6. Accordingly, like reference numerals refer to like elements, and detailed descriptions thereof is not repeated herein.

Referring to FIG. 7, the substrate 500 may be disposed on the porous chuck 200. For example, the adhesive layer 300 and the adsorption pad 400 may be sequentially stacked in the frame 100, the substrate 500 may be fixed to the adsorption pad 400 by providing a negative pressure, and a buffer layer 505 may be formed on the substrate 500.

For example, the substrate 500 may include an insulating material, e.g., glass, quartz and plastic. The plastic may include, e.g., polyethylene terephthalate, polyethylene naphthalate, polyether ketone, polycarbonate, polyarylate, polyether sulfone, polyimide, etc.

The buffer layer 505 may prevent a diffusion of moisture or impurities generated from the substrate 500. The surface of the substrate 500 may be planarized. The buffer layer 505 may include an organic material, an inorganic material or a laminated structure thereof. For example, the buffer layer 505 may have a single layer structure or a multi layer structure of silicon oxide, silicon nitride or silicon oxynitride. In some embodiments, the buffer layer 505 may be omitted.

An amorphous silicon layer 510 may be formed on the buffer layer 505. For example, the amorphous silicon layer 510 may be formed by sputtering, low-pressure chemical vapor deposition (LPCVD), plasma-enhanced chemical vapor deposition (PECVD), etc.

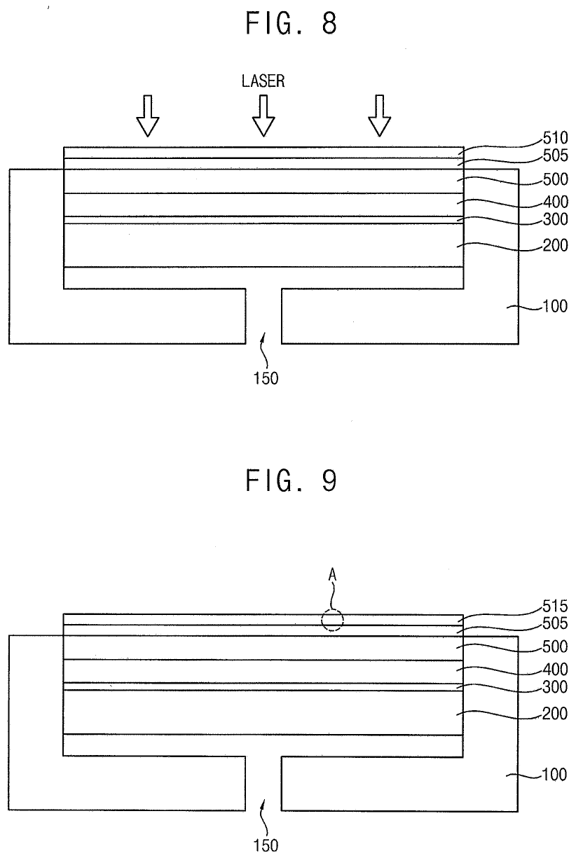

Referring to FIGS. 8 and 9, the amorphous silicon layer 510 may be crystallized to form a polysilicon layer 515. In order to crystallize the amorphous silicon layer 510, the amorphous silicon layer 510 may be irradiated with laser energy. For example, the amorphous silicon layer 510 may be crystallized by excimer laser annealing, sequential lateral solidification, etc. In one embodiment, the amorphous silicon layer 510 may be crystallized by excimer laser annealing.

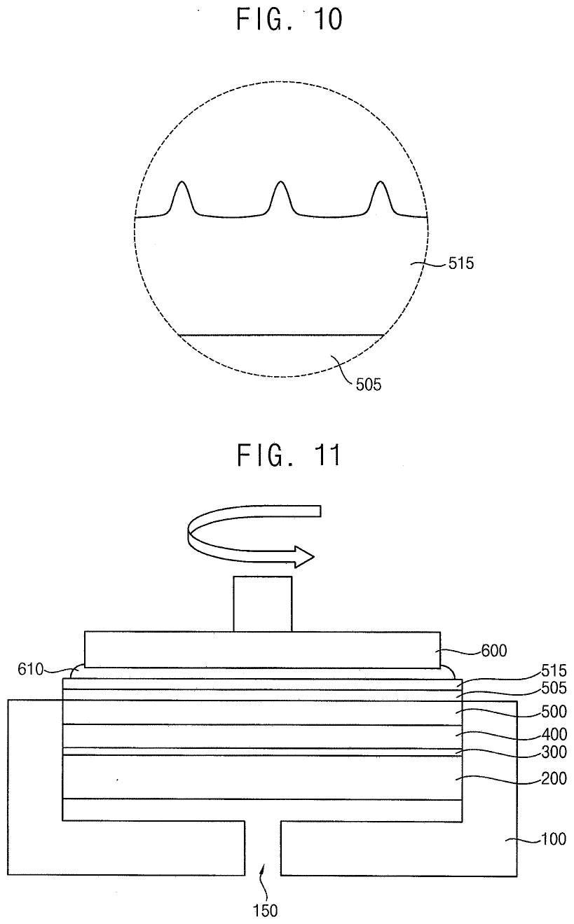

FIG. 10 illustrates an enlarged cross-sectional view of the polysilicon layer 515 in FIG. 9.

Referring to FIG. 10, protrusions of a minute size may be present on an upper surface of the polysilicon layer 515. When crystallized by the laser annealing, the protrusions may be formed at an edge of a grain.

If the protrusions are not removed, the thickness of a gate insulation layer could be increased, so that it could be difficult to provide a high performance thin film transistor.

Referring to FIG. 11, the polysilicon layer 515 may be mechanically and chemically polished using a polishing pad 600 and slurry 610. The polishing pad 600 may have a rotating head. The slurry 610 may be provided between the head of the polishing pad 600 and the polysilicon layer 515.

The slurry 610 may include, e.g., an abrasive particle, a dispersant, a stabilizer, a hydrophilic treatment agent, and water. The abrasive particle may rub against the polysilicon layer 515 to remove the protrusions, and the polysilicon layer 515 may be planarized.

After the polishing using the slurry 610, a buffing process may be further performed. The buffing process may effectively remove the abrasive particles remaining on the surface of the polysilicon layer 515 and defects.

For example, the buffing process may be performed using water (deionized water) and the polishing pad 600 or may be performed using the hydrophilic treatment agent and the polishing pad 600. The hydrophilic treatment agent may be the same as that contained in the slurry. The hydrophilic treatment agent may be provided by being dissolved in water. For example, the buffing process may include a first buffing step of polishing the polysilicon layer 515 by supplying water thereto, and a second buffing step of polishing the polysilicon layer 515 by supplying the hydrophilic treatment agent thereto.

When the buffing step using the hydrophilic treatment agent is further performed, the hydrophilicity of the polysilicon layer 515 may be further increased.

Thereafter, deionized water or the like may be sprayed to clean the polysilicon layer 515. By the cleaning process, the abrasive particle and by-products remaining on the polysilicon layer 515 may be additionally removed.

When the substrate 500 is polished using the polishing pad 600, the hardness of the adsorption pad 400 may not be large and the adsorption pad 400 may have the elasticity. Accordingly, the uniformity of the polishing may be improved by uniformly applying the pressure to the substrate 500, and thus the uniformity of the surface of the substrate may be improved.

The substrate-supporting device in accordance with example embodiments may be used for manufacturing display devices such as liquid crystal displays, organic light emitting devices, or for manufacturing various electronic devices using silicon.

By way of summation and review, in a chemical mechanical polishing (CMP) process for polishing a wafer substrate, a wafer substrate-supporting device of a membrane chuck structure may be used to support the wafer substrate. In this wafer substrate-supporting device of the membrane chuck structure, a wafer may be attracted to a membrane of a silicon material, and then the entire wafer may be uniformly pressurized by applying an air pressure.

When the wafer supporting device of the membrane chuck structure is directly used in a display process, since the size of a display substrate is about 20 times larger than that of a semiconductor wafer substrate, problems such as pressure control, glass breakage, etc., may occur. In response thereto, a glass substrate may be placed on a frame and then air in the frame may be removed to provide a vacuum state inside the frame. However, the pressure applied in a subsequent CMP process may not be uniformly transmitted to the glass substrate, so that a polishing unevenness could occur

Embodiments relate to a substrate-supporting device for supporting a display substrate by vacuum suction for polishing the display substrate and a method of polishing a substrate using the same.

A substrate-supporting device used in a polishing process according to example embodiments may include an adsorption pad disposed between a porous chuck and a substrate, wherein the adsorption pad may include an elastic layer and a porous layer. Accordingly, the pressure may be uniformly applied to the substrate disposed on the adsorption pad, and thus the uniformity of a surface of the substrate after the polishing process may be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. A substrate-supporting device, comprising:
a porous chuck in a frame;
an adsorption pad on the porous chuck; and
an adhesive layer between the porous chuck and the adsorption pad,
wherein:
the adsorption pad includes an elastic layer and a porous layer combined with the elastic layer,
each of the adhesive layer, the elastic layer, and the porous layer includes through-portions respectively extending in a thickness direction, and
the adsorption pad has an Asker C hardness value of 100 or less.

2. The substrate-supporting device as claimed in claim 1, wherein each of the elastic layer and the porous layer of the adsorption pad includes at least one of polyurethane, polyacryl, polydimethylsiloxane (PDMS) and polyurethane acrylate (PUA).

3. The substrate-supporting device as claimed in claim 1, wherein each of the elastic layer and the porous layer of the adsorption pad includes a fabric impregnated with a polymer.

4. The substrate-supporting device as claimed in claim 2, wherein the elastic layer and the porous layer of the adsorption pad include different materials from each other.

5. The substrate-supporting device as claimed in claim 2, wherein the elastic layer and the porous layer of the adsorption pad include a same material.

6. The substrate-supporting device as claimed in claim 1, wherein the porous layer of the adsorption pad includes pores having an average diameter less than 100 μm.

7. The substrate-supporting device as claimed in claim 1, wherein the through-portions have an average diameter less than 100 μm.

8. The substrate-supporting device as claimed in claim 1, wherein the adsorption pad has an Asker C hardness value of 50 or less.

9. The substrate-supporting device as claimed in claim 1, wherein:
the adhesive layer includes first through-portions,
the elastic layer includes second through-portions, and
at least a portion of the first through-portions are connected to the second through-portions.

10. The substrate-supporting device as claimed in claim 1, wherein;
the elastic layer includes second through-portions,
the porous layer includes third through-portions, and
at least a portion of the second through-portions are connected to the third through-portions.

11. The substrate-supporting device as claimed in claim 1, wherein:
the elastic layer includes second through-portions,
the porous layer includes third through-portions, and
the second and third through-portions are aligned and connected to each other.

12. The substrate-supporting device as claimed in claim 1, wherein:
a thickness of the adsorption pad is 800 to 6,000 μm, and
a thickness of each of the elastic layer and the porous layer of the adsorption pad is 400 to 3,000 μm.

13. The substrate-supporting device as claimed in claim 1, wherein the porous chuck is formed of a rigid-body structure including a ceramic material.

14. The substrate-supporting device as claimed in claim 1, wherein the adhesive layer and the adsorption pad are integrally formed as a single unit.

15. A method of polishing a substrate, the method comprising:
disposing a substrate on a substrate-supporting device including a porous chuck, an adhesive layer, and an adsorption pad sequentially stacked in a frame;
fixing the substrate to the substrate-supporting device by applying a negative pressure; and
polishing the substrate using a slurry.

16. The method as claimed in claim 15, wherein the adsorption pad includes an elastic layer and a porous layer combined with the elastic layer,
wherein:
each of the adhesive layer, the elastic layer and the porous layer includes through-portions respectively extending in a thickness direction, and
the adsorption pad has an Asker C hardness value of 100 or less.

17. The method as claimed in claim 15, wherein each of the elastic layer and the porous layer of the adsorption pad includes at least one selected from the group of polyurethane, polyacryl, polydimethylsiloxane (PDMS) and polyurethane acrylate (PUA).

18. The method as claimed in claim 15, wherein each of the elastic layer and the porous layer of the adsorption pad includes a fabric impregnated with a polymer.

19. The method as claimed in claim 15, wherein the substrate includes a silicon layer.

20. The method as claimed in claim 19, wherein the silicon layer includes amorphous silicon or polysilicon.
